(19) United States
(12) Patent Application Publication
(10) Pub. No.: US 2019/0041475 A1
(43) Pub. Date: Feb. 7, 2019

(54) TRANSVERSE ELECTROMAGNETIC (TEM) RADIO FREQUENCY (RF) BODY COIL FOR A MAGNETIC RESONANCE IMAGING (MRI) SYSTEM

(71) Applicant: General Electric Company, Schenectady, NY (US)

(72) Inventors: Saikat Saha, Pewaukee, WI (US); Zhentian Xie, Waukesha, WI (US)

(21) Appl. No.: 15/670,402

(22) Filed: Aug. 7, 2017

(51) Int. Cl. G01R 33/345; G01R 33/422; H01Q 15/00; G01R 33/36; G01R 33/34

(52) U.S. Cl. CPC G01R 33/3453; G01R 33/422; G01R 33/34007; G01R 33/36; H01Q 15/0086

(57) ABSTRACT

A MRI system includes a RF coil assembly, a gradient coil assembly disposed around the RF coil assembly, the gradient coil assembly including a RF shield, and a superconducting magnet assembly disposed around the gradient coil assembly, the superconducting magnet assembly including a vessel containing a plurality of superconducting coils. The RF coil assembly includes a plurality of RF coil elements applied on an outer surface of a hollow cylindrical RF coil former. The plurality of RF coil elements includes a plurality of rungs and a plurality of ground patches that are connected. The plurality of ground patches are spaced apart from the RF shield with a dielectric material in between, and the plurality of ground patches are capacitively coupled to the RF shield. The RF coil assembly is a TEM RF body coil.

### BACKGROUND

Embodiments of the subject matter disclosed herein relate to magnetic resonance imaging (MRI) systems and methods, and more particularly, to a transverse electromagnetic (TEM) RF body coil for a MRI system utilizing ground patches that are capacitively coupled to the radio frequency (RF) shield of the MRI system.

Magnetic resonance imaging (MRI) systems provide a widely accepted and commercially available technique for obtaining digitized visual images representing the internal structure and tissue of subjects having atomic nuclei that are susceptible to nuclear magnetic resonance (NMR). MRI systems include a superconducting magnet that creates a strong, uniform, static, polarizing magnetic field designated as B₀, which is imposed on the nuclei of the subjects being imaged. When a subject is placed in the polarizing magnetic field B₀, the nuclear spins associated with the nuclei in tissue, fluid or other structures become polarized, wherein the individual magnetic moments associated with these spins attempts to align with the polarizing magnetic field B₀, but process about it in random order at their characteristic Larmor frequency, resulting in a small net tissue magnetization along that axis.

MRI systems also include gradient coils that produce smaller amplitude, spatially-varying gradient magnetic fields with orthogonal axes to spatially encode a MR signal by creating a signature resonance frequency at each location in the subject's body. The MRI systems also include RF coils. The RF coils are used to transmit RF excitation signals at or near the resonance frequency of the nuclei, also referred to as the Larmor frequency, which add energy to the nuclear spins of the nuclei. As the nuclear spins relax back to their lower energy normal state, the nuclei release the absorbed energy in the form of a RF signal. This RF signal is detected by the MRI system (RF coil) and is transformed into images of the internal structures and tissue of the subject being imaged.

Various types of RF coils may be used in an MRI system such as a whole-body RF coils (RF body coils) and RF surface (or local) coils. A common RF body coil configuration is the transverse electromagnetic (TEM) coil. A TEM RF body coil is widely applied as high magnetic field parallel MR imaging as transmitting/receiving antennas. Creating a RF ground connection or current return path from the coil elements of a TEM RF body coil to a RF shield has been an issue for TEM RF body coils. The RF ground in a MRI system is generally a RF shield integrated within the gradient coil assembly. The physical connection between the coil elements of a TEM RF body coil may result in mechanical or other physical difficulties that limit the application and/or use of TEM coils in a MRI system. For example, in prior implementations, the coil elements of a TEM RF body coil are physically connected to the RF shield. However, the complexity of RF and gradient coil designs have made direct physical connection very difficult. Some other prior RF body coil designs have utilized a separate RF shield tube structure to create a current return path. However, such a RF shield tube structure is very complex and has a limitation on the spacing of the coil elements.

Accordingly, there is a need for an improved and simplified system and method for coupling RF coil elements of a TEM RF body coil to a RF ground connection or current return path in a MRI system.

### SUMMARY

In accordance with an aspect, a resonance assembly of a magnetic resonance imaging (MRI) system includes a superconducting magnet, a gradient coil assembly disposed within an inner diameter of the superconducting magnet, the gradient coil assembly including a RF shield, and a RF coil assembly disposed within an inner diameter of the gradient coil assembly, the RF coil assembly including a plurality of rungs applied on a RF coil former and a plurality of ground patches applied on the plurality of rungs. Each of the plurality of ground patches are capacitively coupled to the RF shield. The plurality of ground patches are spaced apart from the RF shield with a dielectric material in between the plurality of ground patches and the RF shield. The RF coil assembly is a transverse electromagnetic (TEM) RF body coil.

In accordance with another aspect, a MRI system includes a RF coil assembly, a gradient coil assembly disposed around the RF coil assembly, the gradient coil assembly including a RF shield, and a superconducting magnet assembly disposed around the gradient coil assembly, the superconducting magnet assembly including a vessel containing a plurality of superconducting coils. The RF coil assembly includes a plurality of RF coil elements applied on an outer surface of a hollow cylindrical RF coil former. The plurality of RF coil elements includes a plurality of rungs and a plurality of ground patches that are connected. The plurality of ground patches are capacitively coupled to the RF shield. The plurality of ground patches are spaced apart from the RF shield with a dielectric material in between. The RF coil assembly is a TEM RF body coil.

In accordance with yet another aspect, a resonance assembly for a MRI system includes a plurality of rungs applied on a volume, a plurality of ground patches applied on the plurality of rungs, a RF shield spaced apart from the plurality or ground patches, and a dielectric material disposed between the plurality of ground patches and the RF shield. Each rung in the plurality of rungs has a first end and a second end, and a single ground patch in the plurality of ground patches is applied on the first end of each rung and a single ground patch in the plurality of ground patches is applied on the second end of each rung. The plurality of ground patches are capacitively coupled to the RF shield.

In accordance with yet another aspect, a method of coupling RF coil elements to a RF shield in a TEM RF body coil of a MRI system including providing a plurality of ground patches connected to a plurality of rungs, each of the plurality of ground patches capacitively couple to the RF shield. The method further including applying the plurality of rungs on an outer cylindrical surface of a RF coil former, wherein each of the plurality of rungs has a first end and a second end. The method further including applying the plurality of ground patches on the plurality of rungs, wherein a single ground patch from the plurality of ground patches is connected to the first end of each of the plurality of rungs and a single ground patch from the plurality of ground patches is connected to the second end of each of the plurality of rungs. The plurality of ground patches are spaced apart from the RF shield with a dielectric material in between.

Various other features and advantages will be made apparent from the following detailed description and the drawings.

### BRIEF DESCRIPTION OF THE DRAWINGS

FIG. 1 is a schematic block diagram of an exemplary magnetic resonance imaging (MRI) system in accordance with an embodiment;

FIG. 2 is a schematic cross-sectional diagram of an exemplary resonance assembly of the MRI system of FIG. 1;

FIG. 3 is a perspective diagram of an exemplary RF coil assembly in accordance with an embodiment;

FIG. 4 is an enlarged schematic diagram of a single RF coil element of the exemplary RF coil assembly of FIG. 3;

FIG. 5 is a schematic cross-sectional diagram of a portion of an exemplary resonance assembly in accordance with an embodiment; and

FIG. 6 is an enlarged schematic diagram of a portion of the exemplary resonance assembly of FIG. 5.

### DETAILED DESCRIPTION

Electrically connecting or coupling radio frequency (RF) coil elements of a RF coil assembly in a MRI system to a RF shield, acting as a ground or current return path is very important. However, the physical and structural complexities of the RF coil assembly, gradient coil assembly and RF shield make it difficult, especially with transverse electromagnetic (TEM) RF body coils. Embodiments of the subject matter disclosed herein provide a TEM RF body coil for a MRI system utilizing ground patches that are capacitively coupled to the RF shield of a MRI system, creating an improved and simplified system and method for coupling RF coil elements of a TEM RF body coil to a RF shield in a MRI system. This is a very cost effective and easy implementation of a TEM RF body coil such that the RF coil elements don't need to physically connect to the RF shield.

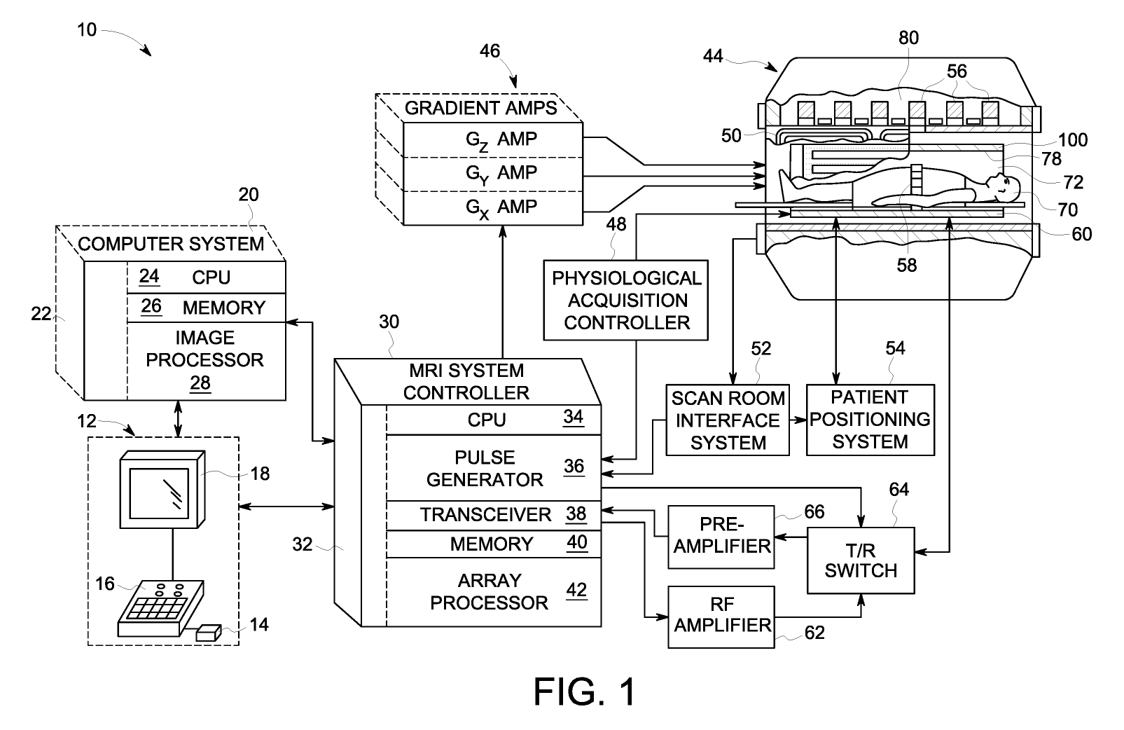

FIG. 1 is a schematic block diagram of an exemplary magnetic resonance imaging (MRI) system 10 in accordance with an embodiment. The operation of MRI system 10 is controlled from an operator workstation 12 that includes an input device 14, a control panel 16, and a display 18. The input device 14 may be a joystick, keyboard, mouse, track ball, touch activated screen, voice control, or any similar or equivalent input device. The control panel 16 may include a keyboard, touch activated screen, voice control, buttons, sliders, or any similar or equivalent control device. The operator workstation 12 is coupled to and communicates with a computer system 20 that enables an operator to control the production and viewing of images on display 18. The computer system 20 includes a plurality of modules that communicate with each other via electrical and/or data connections 22. The computer system connections 22 may be direct wired connections, fiber optic connections, wireless communication links, or the like. The modules of the computer system 20 include a central processing unit (CPU) module 24, a memory module 26, which may include a frame buffer for storing image data, and an image processor module 28. In an alternative embodiment, the image processor module 28 may be replaced by image processing functionality in the CPU module 24. The computer system 20 may be connected to archival media devices, permanent or back-up memory storage, or a network. The computer system 20 is coupled to and communicates with a separate MRI system controller 30.

The MRI system controller 30 includes a set of modules in communication with each other via electrical and/or data connections 32. The MRI system controller connections 32 may be direct wired connections, fiber optic connections, wireless communication links, or the like. The modules of the MRI system controller 30 include a CPU module 34, a pulse generator module 36, which is coupled to and communicates with the operator workstation 12, a transceiver 38, a memory module 40, and an array processor 42. In an alternative embodiment, the pulse generator module 36 may be integrated into the resonance assembly 44 of the MRI system. The MRI system controller 30 is coupled to and receives commands from the operator workstation 12 to indicate the MRI scan sequence to be performed during a MRI scan. The MRI system controller 30 is also coupled to and communicates with a gradient amplifier system 46, which is coupled to a gradient coil assembly 50 to produce magnetic field gradients during a MRI scan.

The pulse generator module 36 may also receive data from a physiological acquisition controller 48 that receives signals from a plurality of different sensors connected to a patient or subject 70 undergoing a MRI scan, such as electrocardiography (ECG) signals from electrodes attached to the patient. And finally, the pulse generator module 36 is coupled to and communicates with a scan room interface system 52, which receives signals from various sensors associated with the condition of the resonance assembly 44. The scan room interface system 52 is also coupled to and communicates with a patient positioning system 54, which sends and receives signals to control movement of a patient table to a desired position for a MRI scan.

The MRI system controller 30 provides gradient waveforms to the gradient amplifier system 46, which is comprised of G_{X}, G_{Y} and G_{Z} amplifiers. Each G_{X}, G_{Y} and G_{Z} gradient amplifier excites a corresponding gradient coil in the gradient coil assembly 50 to produce magnetic field gradients used for spatially encoding MR signals during a MRI scan. The gradient coil assembly 50 is included within the resonance assembly 44, which also includes a superconducting magnet having superconducting coils 56, which in operation, provides a homogenous longitudinal main magnetic field B₀ within an open cylindrical imaging volume 72 that is enclosed by resonance assembly 44. The resonance assembly 44 also includes a RF body coil 60 which in operation, provides a transverse magnetic field B₁ that is generally perpendicular to B₀ throughout the open cylindrical imaging volume 72. The resonance assembly 44 may also include RF surface coils 58 used for imaging different anatomies of a patient undergoing a MRI scan. The RF body coil 60 and RF surface coils 58 may be configured to operate in a transmit and receive mode, transmit mode, or receive mode.

A patient or subject 70 undergoing a MRI scan may be positioned within the open cylindrical imaging volume 72 of the resonance assembly 44. The transceiver module 38 in the MRI system controller 30 produces RF excitation pulses that are amplified by a RF amplifier 62 and provided to the RF body coil 60 and RF surface coils 58 through a transmit/receive switch (T/R switch) 64.

As mentioned above, RF body coil 60 and RF surface coils 58 may be used to transmit RF excitation pulses and/or to receive resulting MR signals from a patient undergoing a MRI scan. The resulting MR signals emitted by excited nuclei in the patient undergoing a MRI scan may be sensed and received by the RF body coil 60 or RF surface coils 58 and sent back through the T/R switch 64 to a pre-amplifier 66. The amplified MR signals are demodulated, filtered and digitized in the receiver section of the transceiver 38. The T/R switch 64 is controlled by a signal from the pulse generator module 36 to electrically connect the RF amplifier 62 to the RF body coil 60 during the transmit mode and connect the pre-amplifier 66 to the RF body coil 60 during the receive mode. The T/R switch 64 may also enable RF surface coils 58 to be used in either the transmit mode or receive mode.

The resulting MR signals sensed and received by the RF body coil 60 are digitized by the transceiver module 38 and transferred to the memory module 40 in the MRI system controller 30.

A MR scan is complete when an array of raw k-space data, corresponding to the received MR signals, has been acquired and stored temporarily in the memory module 40 until the data is subsequently transformed to create images. This raw k-space data is rearranged into separate k-space data arrays for each image to be reconstructed, and each of these separate k-space data arrays is input to the array processor 42, which operates to Fourier transform the data into arrays of image data.

The array processor 42 uses a known transformation method, most commonly a Fourier transform, to create images from the received MR signals. These images are communicated to the computer system 20 where they are stored in memory module 26. In response to commands received from the operator workstation 12, the image data may be archived in long-term storage or it may be further processed by the image processor module 28 and conveyed to the operator workstation 12 for presentation on the display 18.

In alternative embodiments, the modules of computer system 20 and MRI system controller 30 may be implemented on the same computer system or a plurality of computer systems.

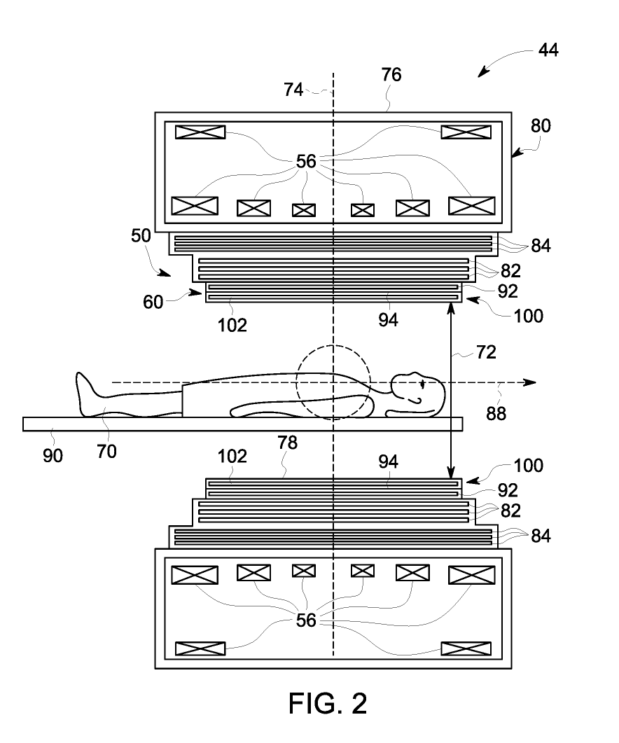

FIG. 2 is a schematic cross-sectional diagram of an exemplary resonance assembly 44 of the MRI system 10 of FIG. 1. Resonance assembly 44 is cylindrical in shape having a vertical center axis 74, a longitudinal center axis 88, and includes, among other elements, a superconducting magnet assembly 80, a gradient coil assembly 50 and a RF coil assembly 100. Various other elements such as covers, supports, suspension members, end caps, brackets, etc. are omitted from FIG. 2 for clarity.

An open cylindrical imaging volume 72 is surrounded by a patient bore tube 78. RF coil assembly 100 is cylindrical and is disposed around the patient bore tube 78 and mounted inside of and adjacent to the cylindrical gradient coil assembly 50. The gradient coil assembly 50 is disposed around the RF coil assembly 100 in a spaced-apart coaxial relationship and the gradient coil assembly 50 circumferentially surrounds the RF coil assembly 100. Gradient coil assembly 50 is mounted inside of and adjacent to superconducting magnet assembly 80 and is circumferentially surrounded by superconducting magnet assembly 80. As shown in FIG. 2, resonance assembly 44 includes a superconducting magnet assembly 80, a gradient coil assembly 50 disposed within an inner diameter of the superconducting magnet assembly 80, the gradient coil assembly 50 including a RF shield 92, and a RF coil assembly 100 disposed within an inner diameter of the gradient coil assembly 50.

A patient or subject 70 undergoing a MRI scan may be placed into the resonance assembly 44 along a longitudinal center axis 88 (e.g., z axis) on a patient table 90. Center axis 88 is aligned along the patient bore tube axis of the resonance assembly 44 and along the direction of the main magnetic field, B₀, generated by superconducting magnet assembly 80. RF body coil 60 may be used to apply RF excitation pulses to the patient 70 and may be used to receive emitted RF signals back from the patient. Gradient coil assembly 50 generates magnetic field gradients used for spatially encoding MR signals during a MRI scan.

Superconducting magnet assembly 80 may include, for example, several radially aligned and longitudinally spaced apart superconductive coils 56, each capable of carrying a large current. The superconductive coils 56 are designed to create a homogenous longitudinal magnetic field, B₀, within the open cylindrical imaging volume 72. The superconductive coils 56 are enclosed in a vessel 76. The vessel 76 is designed to maintain the temperature of the superconducting coils 56 below the appropriate critical temperature so that the superconducting coils 56 are in a superconducting state with zero resistance. Vessel 76 may include, for example, a helium vessel (not shown) and thermal shields (not shown) for containing and cooling the superconducting coils in a known manner. The vessel 76 is configured to maintain a vacuum and to prevent heat from being transferred to the superconducting magnet assembly 80.

Gradient coil assembly 50 comprises a cylindrical inner gradient coil set 82 and a cylindrical outer gradient coil set 84 positioned in concentric arrangement with respect to the longitudinal center axis 88. Inner gradient coil set 82 includes X, Y and Z gradient coils and outer gradient coil set 84 includes the respective outer X, Y and Z gradient coils. The gradient coils may be activated by passing an electric current through the coils to generate a gradient field in the open cylindrical imaging volume 72 as required in MR imaging. The gradient coil assembly 50 also includes a cylindrical RF shield 92 that is integrated within the gradient coil assembly 50 and is adjacent to and formed about an inner surface of the inner gradient coil set 82.

The RF shield 92 is the innermost layer of the gradient coil assembly 50. The RF shield 92 may be made of a conductive material, such as copper, a stainless steel mesh, or any other conductive material and potted with an epoxy resin or a glass tape.

The RF shield 92 functions as an essential element of the MRI system 10, providing a ground or current return path for RF coil elements 102 of the RF body coil 60, and to shield RF signals and electromagnetic interference from the gradient coil assembly 50 and superconducting magnet assembly 80. The RF shield 92 de-couples the RF body coil 60 from the gradient coil assembly 50.

The resonance assembly 44 also includes a RF coil assembly 100, which includes a RF coil former 94 and RF coil elements 102 to create RF body coil 60. The RF coil assembly 100 may be mounted inside the gradient coil assembly 50 in a spaced apart coaxial relationship. The RF coil assembly 100 functions to provide a transverse magnetic field B₁ that is generally perpendicular to B₀ throughout the open cylindrical imaging volume 72. The RF body coil 60 also transmits RF excitation pulses and receives resulting MR signals from a patient undergoing a MRI scan.

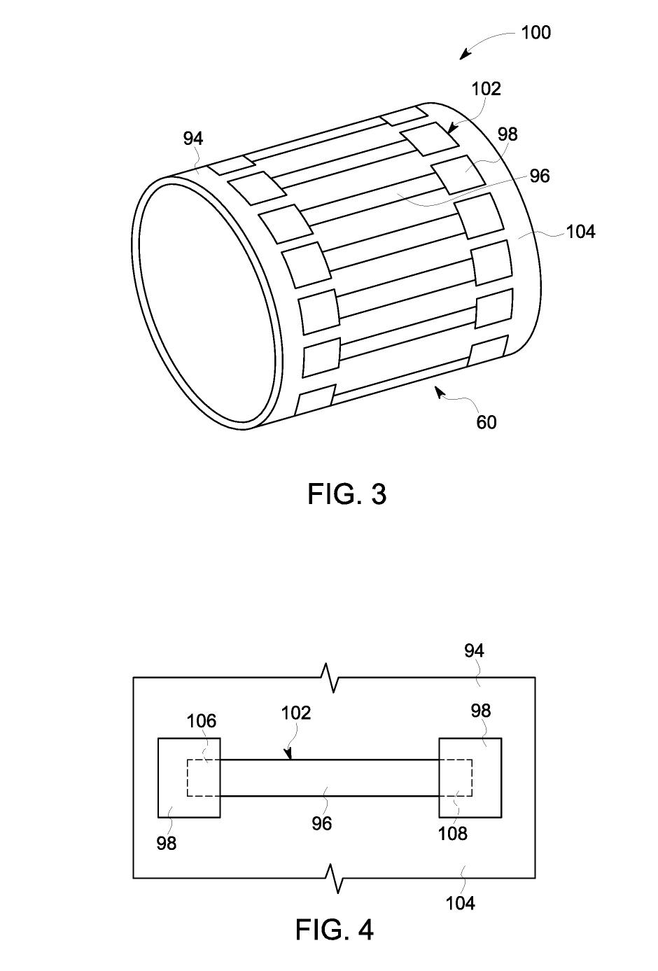

FIG. 3 is a perspective diagram of an exemplary RF coil assembly 100 in accordance with an embodiment. The RF coil assembly 100 includes a RF coil former or hollow cylindrical tube 94 and a plurality of RF coil elements 102 mounted around an outer cylindrical surface 104 of the RF coil former 94 to create a RF body coil 60. The RF coil former 94 may be composed of a fiberglass or fiber reinforced plastic (FRP) cylinder, although it is recognized that other suitable materials may also be used. The plurality of RF coil elements 102 are formed on the outer cylindrical surface 104 of the RF coil former 94.

Various types of RF body coils may be used in an MRI system such as a whole-body RF coil (RF body coil) and RF surface (or local) coils. A common RF body coil configuration is the transverse electromagnetic (TEM) coil. A TEM RF body coil is widely applied as high magnetic field parallel MR imaging as transmitting/receiving antennas. The RF coil assembly 100 shown in FIG. 3 illustrates a TEM RF body coil 60.

The RF coil elements 102 include a plurality of rungs 96 disposed on the outer cylindrical surface 104 of the RF coil former 94 and a plurality of ground patches 98 connected to the plurality of rungs 96 as shown in FIG. 4. Each of the plurality of rungs 96 has a first end 106 and a second end 108 that is opposite the first end. A single ground patch 98 from the plurality of ground patches is connected to the first end 106 of each of the plurality of rungs 96 and a single ground patch 98 from the plurality of ground patches is connected to the second end 108 of each of the plurality of rungs. The plurality of rungs 96 extend longitudinally on the outer cylindrical surface 104 of the RF coil former 94. The plurality of ground patches 98 are physically and electrically connected to the first 106 and second 108 ends of the plurality of rungs 96.

The plurality of rungs 96 and plurality of ground patches 98 are disposed around the outer cylindrical surface 104 of RF coil former 94. An exemplary number of rungs are shown in FIG. 3. However, fewer or more rungs may be used depending upon specific design requirements. The plurality of rungs 96 are arranged cylindrically around the outer cylindrical surface 104 of the RF coil former 94 and may be, for example, uniformly spaced apart from one another. The plurality of rungs 96 and plurality of ground patches 98 may be constructed from conventional materials with high electrical conductivity such as copper or other highly conductive material. In various embodiments, the plurality of rungs 96 and plurality of ground patches 98 may be a conductive foil, a conductive tape, thin sheets of conductive material, etc.

FIG. 4 is an enlarged schematic diagram of a single RF coil element 102 comprising a single rung 96 and two ground patches 98 coupled to the ends 68 of the rung 96 of the exemplary RF coil assembly 100 of FIG. 3. The RF coil former 94 acts as a substrate and may be composed of a fiberglass or FRP cylinder acts as a substrate for the plurality of rungs 96 and plurality of ground patches 98 that are applied on its outer cylindrical surface 104. A plurality of rungs 96, composed of a conductive material, are applied on the outer cylindrical surface 104 of the RF coil former 94. A plurality of ground patches 98, also composed of a conductive material, are applied over first 106 and second 108 ends of the plurality of rungs 96. The plurality of ground patches 98 are physically and electrically connected to the first 106 and second 108 ends of the plurality of rungs 96, such as by soldering or other electrical and physical bonding method. The plurality of rungs 96 and plurality of ground patches 98 may be potted with an epoxy resin or a glass tape.

As shown in FIG. 4, each rung 96 has a first end 106 and a second end 108 that is opposite the first end. A first ground patch 98 is physically and electrically connected to the first end 106 of rung 96 and a second ground patch 98 is physically and electrically connected to the second end 108 of rung 96. In an exemplary embodiment, the width of each ground patch 98 is larger than the width of each rung 96 to optimize the functionality of the TEM RF body coil.

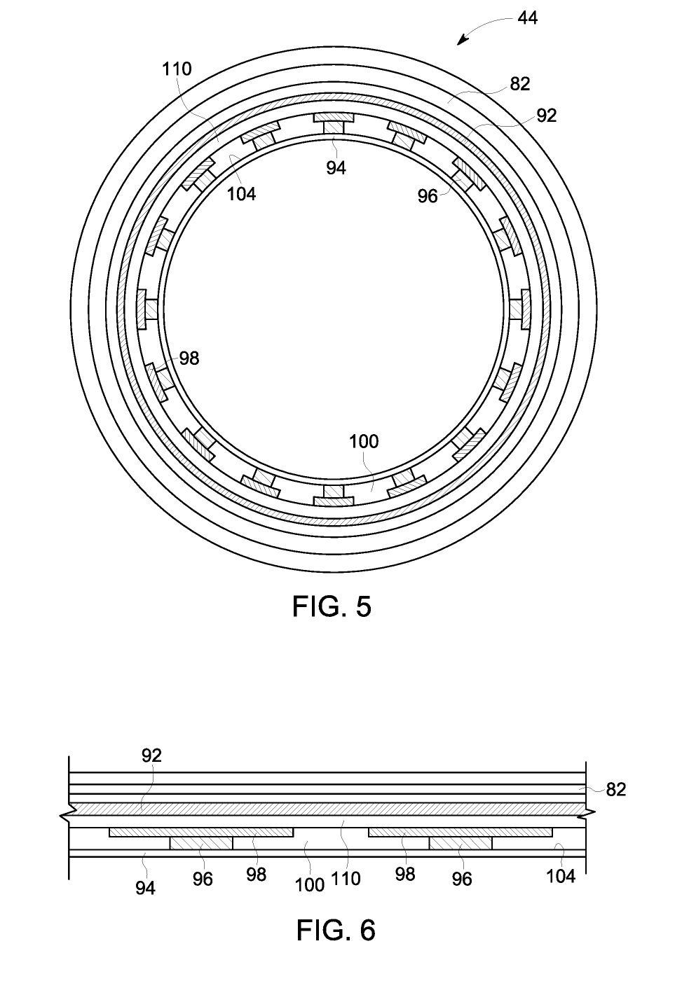

FIG. 5 is a schematic cross-sectional diagram of a portion of an exemplary resonance assembly 44 in accordance with an embodiment. The superconducting magnet assembly 80 and outer gradient coil set 84 of the gradient coil assembly are not shown. In FIG. 5, the RF coil assembly 100 is mounted inside of the inner gradient coil set 82 in a spaced apart coaxial relationship. The RF coil assembly 100 includes a plurality of rungs 96 applied on an outer cylindrical surface 104 of a RF coil former 94 and a plurality of ground patches 98 applied over the plurality of rungs 96. The plurality of ground patches 98 are physically and electrically connected to the plurality of rungs 96, such as by soldering or other electrical and physical bonding method. The plurality of rungs 96 and plurality of ground patches 98 may be potted with an epoxy resin or a glass tape.

A RF shield 92 integrated within and positioned adjacent to the inner gradient coil set 82 is spaced apart from the plurality of ground patches 98 by a dielectric material 110. The RF shield 92 is the innermost layer of inner gradient coil set 82 and located closest to the ground patches 98. The plurality of ground patches 98 are spaced apart from the RF shield 92 with a dielectric material 110 in between the plurality of ground patches 98 and the RF shield 92. Each ground patch 98 capacitively couples to the RF shield 92. There is no physical connection between the plurality of rungs 96 and the RF shield 92 and no physical connection between the plurality of ground patches 98 and the RF shield 92.

FIG. 6 is an enlarged schematic diagram of a portion of the exemplary resonance assembly 44 of FIG. 5. As can be seen in FIG. 6, each of the plurality of rungs 96 are physically isolated from each other and physically isolated from the RF shield 92. A first ground patch is physically and electrically connected to the first end of each rung and a second ground patch is physically and electrically connected to the second end of each rung. Each ground patch 98 is spaced apart from, but capacitively couples to the RF shield 92 through dielectric material 110. The RF shield 92 is the innermost layer of the inner gradient coil set 82. The RF shield 92 is spaced apart from the ground patches 98 by dielectric material 110 that substantially inhibits electrical charges from flowing therethrough, but forms a capacitor.

In an exemplary embodiment, the width of each ground patch 98 is larger than the width of each rung 96 to optimize the functionality of the TEM RF body coil. Also, the type of dielectric material used and its depth may be selected and optimized to provide good capacitive coupling between the ground patches 98 and RF shield 92. The ground patches 98 provide a current return path from the rungs 96 to the RF shield 92.

This written description uses examples to disclose the invention, including the best mode, and also enables any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A resonance assembly of a magnetic resonance imaging (MRI) system, the resonance assembly comprising:
a superconducting magnet;
a gradient coil assembly disposed within an inner diameter of the superconducting magnet, the gradient coil assembly including a RF shield; and
a RF coil assembly disposed within an inner diameter of the gradient coil assembly, the RF coil assembly comprising:
a plurality of rungs applied on a RF coil former; and
a plurality of ground patches applied on the plurality of rungs; and
wherein each of the plurality of ground patches are capacitively coupled to the RF shield.

2. The resonance assembly of claim 1, wherein the plurality of ground patches are spaced apart from the RF shield with a dielectric material in between.

3. The resonance assembly of claim 2, wherein each of the plurality of rungs has a first end and a second end.

4. The resonance assembly of claim 3, wherein a single ground patch from the plurality of ground patches is connected to the first end of each of the plurality of rungs and a single ground patch from the plurality of ground patches is connected to the second end of each of the plurality of rungs.

5. The resonance assembly of claim 1, wherein the plurality of rungs are applied on an outer cylindrical surface of the RF coil former.

6. The resonance assembly of claim 1, wherein the plurality of rungs are arranged cylindrically around an outer surface of the RF coil former and are uniformly spaced apart from one another.

7. The resonance assembly of claim 1, wherein the RF coil assembly is a transverse electromagnetic (TEM) RF body coil.

8. The resonance assembly of claim 1, wherein the plurality of rungs and the plurality of ground patches are a conductive foil.

9. The resonance assembly of claim 1, wherein the plurality of rungs and the plurality of ground patches are a conductive tape.

10. The resonance assembly of claim 1, wherein the plurality of rungs and the plurality of ground patches are a thin conductive sheet.

11. A magnetic resonance imaging (MRI) system comprising:
a RF coil assembly;
a gradient coil assembly disposed around the RF coil assembly, the gradient coil assembly including a RF shield; and
a superconducting magnet assembly disposed around the gradient coil assembly, the superconducting magnet assembly including a vessel containing a plurality of superconducting coils;
wherein the RF coil assembly includes a plurality of RF coil elements applied on an outer surface of a hollow cylindrical RF coil former; and
wherein the plurality of RF coil elements includes a plurality of rungs and a plurality of ground patches; and
wherein the plurality of ground patches are capacitively coupled to the RF shield.

12. The MRI system of claim 11, wherein the plurality of ground patches are spaced apart from the RF shield with a dielectric material in between.

13. The MRI system of claim 12, wherein the plurality of ground patches are physically and electrically connected to the plurality of rungs.

14. The MRI system of claim 12, wherein each rung in the plurality of rungs has a first end and a second end and the first end is connected to a ground patch from the plurality of ground patches and the second end is connected to a ground patch from the plurality of ground patches.

15. The MR system of claim 11, wherein the RF coil assembly is a transverse electromagnetic (TEM) RF body coil.

16. A resonance assembly for a MRI system comprising:
a plurality of rungs applied on a volume;
a plurality of ground patches applied on the plurality of rungs;
a RF shield spaced apart from the plurality or ground patches; and
a dielectric material disposed between the plurality of ground patches and the RF shield;
wherein each rung in the plurality of rungs has a first end and a second end, and a single ground patch in the plurality of ground patches is applied on the first end of each rung and a single ground patch in the plurality of ground patches is applied on the second end of each rung; and
wherein the plurality of ground patches are capacitively coupled to the RF shield.

17. A method of coupling RF coil elements to a RF shield in a TEM RF body coil of a MRI system, the method comprising:
providing a plurality of ground patches connected to a plurality of rungs, each of the plurality of ground patches capacitively couple to the RF shield.

18. The method of claim 17, further comprising the step of applying the plurality of rungs on an outer cylindrical surface of a RF coil former, wherein each of the plurality of rungs has a first end and a second end.

19. The method of claim 18, further comprising the step of applying the plurality of ground patches on the plurality of rungs, wherein a single ground patch from the plurality of ground patches is connected to the first end of each of the plurality of rungs and a single ground patch from the plurality of ground patches is connected to the second end of each of the plurality of rungs.

20. The method of claim 17, wherein the plurality of ground patches are spaced apart from the RF shield with a dielectric material in between.
